(19) United States
(12) Patent Application Publication
(10) Pub. No.: US 2023/0186004 A1
(43) Pub. Date: Jun. 15, 2023

(54) INTEGRATED CIRCUIT DESIGN VERTFICATION

(71) Applicant: XEPIC CORPORATION LIMITED, Nanjing (CN)

(72) Inventor: Jiahua ZHU, Hopkinton, MA (US)

(21) Appl. No.: 17/562,987

(22) Filed: Dec. 27, 2021

(30) Foreign Application Priority Data
Dec. 9, 2021 (CN) 202111498735.8

(51) Int. Cl. G06F 30/33

(52) U.S. Cl. CPC G06F 30/33

(57) ABSTRACT

A method of verifying an integrated circuit (IC) design includes: obtaining a description of the IC design; determining whether the IC design includes a combinational loop based on the description, where the combinational loop includes an output and an input connected to the output; and in response to the IC design including the combinational loop, unrolling the combinational loop into an unrolled loop, the unrolled loop including: a first iteration and a second iteration connected to form the unrolled loop, where the first iteration includes a first output and a first input, the second iteration includes a second output and a second input, and the second output is connected to the first input; and a register connected between the first input and the second output; and verifying the IC design with the unrolled loop.

### CROSS REFERENCE TO RELATED APPLICATION

This application claims priority to Chinese Patent Application No. 202111498735.8, filed Dec. 9, 2021, which is incorporated herein by reference in its entirety.

### TECHNICAL FIELD

The present disclosure relates to the technical field of integrated circuit (IC) chip design verification and, more particularly, to a method and an apparatus for verifying an IC design, such as a very large-scale integration circuit (VLSI) design.

### BACKGROUND

An integrated circuit (IC) chip design is often verified before the chips are manufactured. For example, the IC chip design is often verified by running a hardware description code of the IC chip on a plurality of field programmable gate arrays (FPGAs) to emulate the IC chip, or running a software programming code of a testbench with stimuli on a computer to verify the IC chip. Occasionally, the IC design may include a combinational loop, which is often a design error. The combinational loop is a loop where an output of a combinational gate feeds back to an input of the same combinational gate without passing through any sequential element in between. During design verification, the output of the combinational loop becomes uncertain and oscillates between 0 and 1. Further, continuous oscillation may even damage FPGAs.

### SUMMARY

In accordance with the disclosure, there is provided a method of verifying an integrated circuit (IC) design. The method includes: obtaining a description of the IC design; determining whether the IC design includes a combinational loop based on the description, where the combinational loop includes an output and an input connected to the output; and in response to the IC design including the combinational loop, unrolling the combinational loop into an unrolled loop, the unrolled loop including: a first iteration and a second iteration connected to form the unrolled loop, where the first iteration includes a first output and a first input, the second iteration includes a second output and a second input, and the second output is connected to the first input; and a register connected between the first input and the second output; and verifying the IC design with the unrolled loop, where each of the first iteration and the second iteration includes same components as the combinational loop.

Also in accordance with the disclosure, there is provided an apparatus for verifying an integrated circuit (IC) design. The apparatus includes a memory storing program instructions; and at least one processor configured to execute the program instructions to perform obtaining a description of the IC design; determining whether the IC design includes a combinational loop based on the description, where the combinational loop includes an output and an input connected to the output; and in response to the IC design including the combinational loop, unrolling the combinational loop into an unrolled loop, the unrolled loop including: a first iteration and a second iteration connected to form the unrolled loop, where the first iteration includes a first output and a first input, the second iteration includes a second output and a second input, and the second output is connected to the first input; and a register connected between the first input and the second output; and verifying the IC design with the unrolled loop, where each of the first iteration and the second iteration includes same components as the combinational loop.

Also in accordance with the disclosure, there is provided a non-transitory computer-readable storage medium storing a set of instructions, the set of instructions is executable by at least one processor of a computing system to cause the computing system to perform a method for verifying an IC design, the method comprising: obtaining a description of the IC design; determining whether the IC design includes a combinational loop based on the description, where the combinational loop includes an output and an input connected to the output; and in response to the IC design including the combinational loop, unrolling the combinational loop into an unrolled loop, the unrolled loop including: a first iteration and a second iteration connected to form the unrolled loop, where the first iteration includes a first output and a first input, the second iteration includes a second output and a second input, and the second output is connected to the first input; and a register connected between the first input and the second output; and verifying the IC design with the unrolled loop, where each of the first iteration and the second iteration includes same components as the combinational loop.

### BRIEF DESCRIPTION OF THE DRAWINGS

FIG. 1 is a schematic diagram showing an exemplary combinational loop.

FIG. 2 is a schematic diagram showing an exemplary method of addressing a combinational loop.

FIG. 3 is a flowchart showing an exemplary method of verifying an integrated circuit (IC) design according to some embodiments of the present disclosure.

FIG. 4 is a schematic diagram showing another exemplary combinational loop according to some embodiments of the present disclosure.

FIG. 5 is a schematic diagram showing an exemplary method of addressing the exemplary combinational loop in FIG. 4 according to some embodiments of the present disclosure.

FIG. 6 is a structural diagram showing an exemplary apparatus for verifying an IC design according to some embodiments of the present disclosure.

### DETAILED DESCRIPTION OF THE EMBODIMENTS

Embodiments of the present disclosure are described in detail below with reference to the accompanying drawings. Same or similar reference numerals in the drawings represent the same or similar elements or elements having the same or similar functions throughout the specification. The described embodiments are some rather than all of the embodiments of the present disclosure. Other embodiments obtained by those having ordinary skills in the art on the basis of the described embodiments without inventive efforts should fall within the scope of the present disclosure. Unless there is conflict, the following embodiments and/or features of the embodiments can be combined with each other.

A logic system design (e.g., an integrated circuit (IC) chip) needs to be verified before being finalized for production. The verification of the logic system design can be achieved by emulating the logic system design using one or more field programmable gate arrays (FPGAs). The emulation of the logic system design can include compiling the hardware description language (HDL) codes of the logic system design into a gate-level netlist and implementing the gate-level netlist on the one or more FPGAs configured to mimic the logic system design. Running the emulated logic design system on the FPGAs can result in waveforms of the logic design system being generated for further verification. The logic system design can be further verified by simulating the logic system design on a computer without involving any FPGAs.

Consistent with the disclosure, the design of an integrated circuit can be described in an HDL source code or a RTL code. HDL source code can be written in Verilog, SystemVerilog, or very high-speed integrated circuit hardware description language (VHDL). The integrated circuit can be, e.g., a very large-scale integration (VLSI) device. The HDL source code can be compiled by a hardware compiler or an HDL compiler to generate a netlist to be implemented on a simulator or a hardware emulation device. The hardware emulation device can include one or more FPGAs. Further, a testbench (TB) with stimuli can be described in a software programming language source code written in a software programming language, such as C, C++, or Python. The software programming language source code can be compiled by a software compiler or a programming language compiler to generate a binary executable code to be executed by a computer.

The logic system design may include a combinational loop, which may cause problems for the emulation and the simulation of the logic system design.

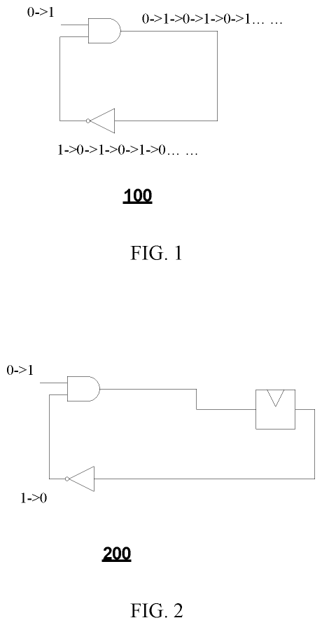

FIG. 1 shows an example combinational loop 100 including an AND gate and a NOT gate connected to each other. A first input of the AND gate can be input from another part of the logic system design, and an output of the AND gate is inverted and fed back to a second input of the AND gate without passing through a sequential element such as a register, a flip-flop, or a counter, etc. In this case, when the first input of the AND gate transitions from 0 to 1, the output and the second input of the AND gate oscillate between 0 and 1. In an emulation process, timing of a signal path through the AND gate may not be determined, and an FPGA emulating the AND gate may be damaged due to continuous oscillation. In a simulation process, the continuous oscillation becomes an endless loop, and the simulation may not converge other cases, the simulation may be slowed by the endless loop.

Because the combinational loop does not include a sequential element, one approach to break the combinational loop is to insert a register in the signal path of the combinational loop.

FIG. 2 is a schematic diagram showing an exemplary method of addressing a combinational loop 200. As shown in FIG. 2, when the first input of the AND gate transitions from 0 to 1, the output changes from 0 to 1 and the second input of the AND gate changes from 1 to 0. In the emulation process, the timing of the signal path through the AND gate can be determined. In the simulation process, presence of the combinational loop can be detected during statical analysis or compilation of the HDL source code and the oscillation can be detected during runtime. However, the inserted register may change the behavior of the logic system design. The continuous oscillation may not be detected in the emulation process. Although the continuous oscillation can be detected in the simulation process, determining the continuous oscillation can be time-consuming and costly. In some cases, the oscillation can be designed for a certain purpose, and if altered behavior of the logic system design cannot produce the oscillation, the verification of the logic system design also fails to meet its most important criteria. Thus, the verification of the logic system design shall avoid the side effects of oscillation, yet still be capable of detecting the occurrence of the oscillation.

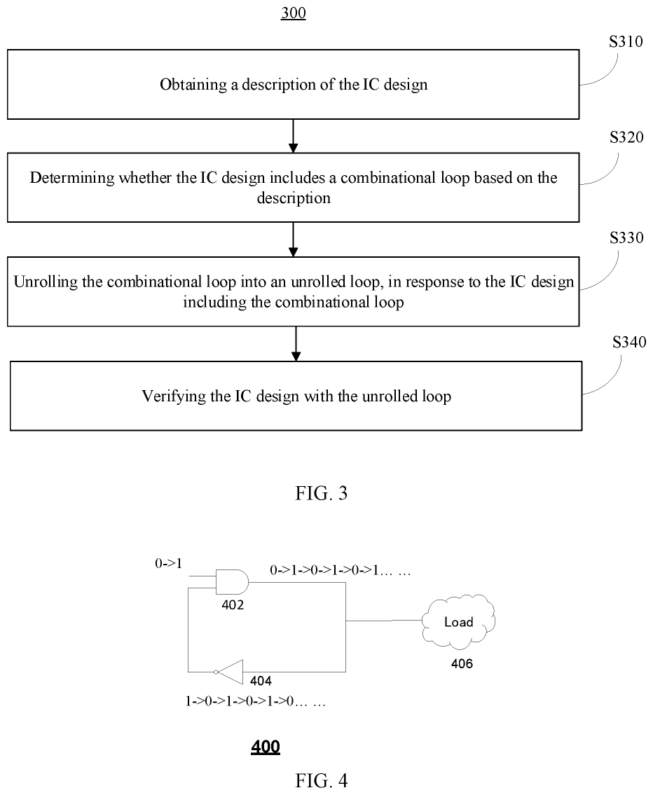

FIG. 3 is a flowchart showing an exemplary method 300 for verifying an IC design, such as a VLSI design, according to some embodiments of the present disclosure.

As shown in FIG. 3, at S310, a description of the IC design can be obtained. In some embodiments, the description of the IC design includes at least one of a source code in HDL language (such as Verilog, VHDL, and the like), a netlist, or a register transfer level (RTL) code. In some embodiments, the description of the IC design further includes a verification environment. The verification environment can include a code describing a testbench (e.g., universal verification methodology (UVM) test bench) with stimuli in a software programming language.

In some embodiments, the IC is a VLSI device and can be described in the IC design source code using an HDL. The HDL can be at least one of Verilog, SystemVerilog, or VHDL. The testbench with the stimuli can be captured in the verification environment source code. The testbench can be configured to test the IC design.

At S320, whether the IC design includes a combinational loop can be determined based on the description.

In some embodiments, the IC design may include a combinational loop. During compilation of the IC design source code, for example, statical analysis can be performed to determine whether the IC design includes a combinational loop. If the statical analysis reveals that the IC design shows characteristics of a combinational loop, it can be determined that a combinational loop exists in the IC design. Performing statical analysis to determine whether the IC design includes a combinational loop is also referred to as statically detecting a combinational loop.

FIG. 4 shows an example circuit 400 that includes an AND gate 402 and a NOT gate 404, where a primary input of the circuit 400 providing an initial signal is connected to an input of the AND gate 402 and an output of the AND gate 402 is connected to loads 406. The circuit 400 can be part of an IC design. During compilation of the IC design source code, the statical analysis reveals that an output signal of the AND gate 402 is fed back to a feedback input of the AND gate 402 without passing through a sequential element such as a register, the circuit 400 is determined to be a combinational loop having the structure and connections shown in FIG. 4, i.e., the output of the AND gate 402 is also connected to the feedback input of the AND gate 402 via the NOT gate 404. In this circuit, the output signal of the AND gate 402, in addition to being sent to the loads, is also fed back to the feedback input of the AND gate 402 via the NOT gate 404. FIG. 4 merely shows an example combinational loop. In some other embodiments, a combinational loop can have a more complicated or a simpler structure. For example, a combinational loop can include a NOT gate with the input and output thereof being connected to each other.

With reference back to FIG. 3, at S330, upon determining that the IC design includes a combinational loop, the combinational loop can be unrolled into an unrolled loop. Unrolling the combinational loop can refer to replacing the combinational loop with an unrolled loop. Unrolling a combinational loop can be performed prior to the time of emulation and simulation.

In some embodiments, an unrolled loop includes two or more connected iterations, such as a first iteration and a second iteration connected together. The connected first and second iterations can form the unrolled loop. Below, the description of embodiments will be made using an example of an unrolled loop having two connected iterations. In some embodiments, in the unrolled loop, the first iteration includes a first output and a first input, the second iteration includes a second output and a second input, and the second output is connected to the first input. In other words, an output of the second iteration is connected to the first input of the first iteration. The unrolled loop can also include a register inserted between the first iteration and the second iteration, such as between the first input of the first iteration and the second output of the second iteration.

The unrolled loop can further include a comparator connected to the outputs of the first and second iterations and configured to determine whether an oscillation occurs in the combinational loop.

In some embodiments, the first output of the first iteration can be connected to a first input of the comparator, the second output of the second iteration can be connected to a second input of the comparator.

In determining whether the oscillation occurs in the combination loop, the comparator can be configured to determine whether the first output and the second output are same; and in response to determining the first output and the second output being same, providing a comparison output indicating occurrence of oscillation in the combination loop.

In some embodiments, the comparator can compare the first output of the first iteration with the second output of the second iteration and the comparison output of the comparator can be used to indicate whether oscillation has occurred. For example, when the first output of the first iteration and the second output of the second iteration are the same, the comparator outputs 0, which indicates that oscillation occurs in the combinational loop. On the other hand, when the first output of the first iteration and the second output of the second iteration are different, the comparator outputs 1, which indicates that there is no oscillation in the combinational loop.

In some embodiments, method 300 can further include generating an oscillation warning in response to receiving from the comparator the comparison output indicating the occurrence of the oscillation. Thus, though the oscillation is omitted in the unrolled loop, the occurrence of the oscillation can still be detected and warned.

Consistent with the disclosure, each of the first and second iterations can include a “copy” of the combinational loop. For example, each of the iterations can include all the components (gates) of the combinational loop but the connections between the components (gates) in the iteration can be different from those in the combinational loop. Instead of feeding the output of the combinational loop directly back to an input of the combinational loop, in the unrolled loop, the output of one iteration is fed to an input of another iteration. That is, the original combinational loop is “unrolled” into two iterations. Further, the register can be added to stop or reduce possible oscillation from occurring in the unrolled loop.

In some embodiments, a load of the combinational loop can be connected to an output of the second iteration.

In some embodiments, the combinational loop further includes a primary input, and the primary input is connected to a third input of the first iteration and a fourth input of the second iteration.

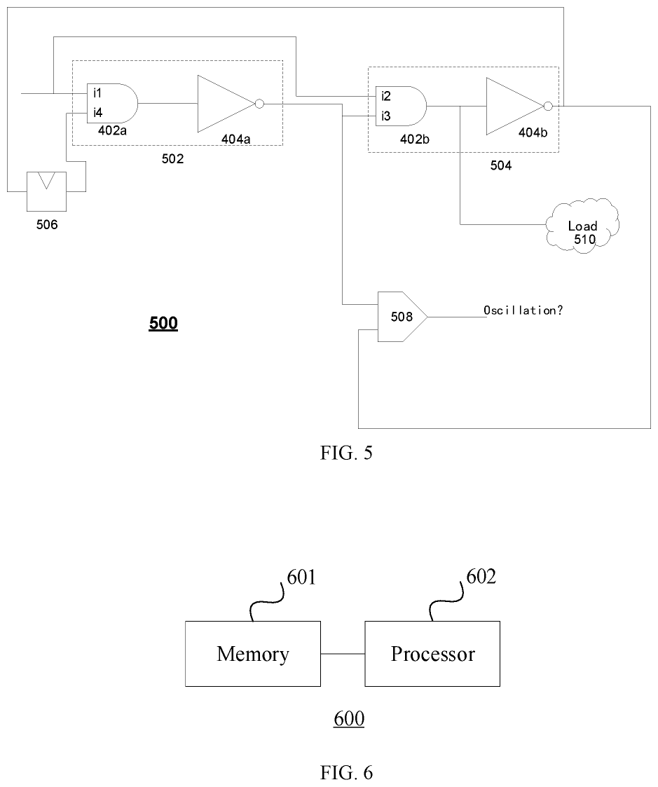

FIG. 5 is a schematic diagram showing an exemplary method of addressing the exemplary combinational loop in FIG. 4 according to some embodiments of the present disclosure.

For example, the example combinational loop 400 shown in FIG. 4 can be unrolled into an example unrolled loop 500 shown in FIG. 5. As shown in FIG. 5, the unrolled loop 500 includes a first iteration 502 and a second iteration 504 connected to the first iteration 502. Each of the first iteration 502 and the second iteration 504 includes same components of the combinational loop 400. Specifically, the first iteration 502 includes an AND gate 402a and a NOT gate 404a, and the second iteration 504 includes an AND gate 402b and a NOT gate 404b. A signal input “i1” of the AND gate 402a of the first iteration 502 and a signal input “i2” of the AND gate 402b of the second iteration 504 are connected to each other and configured to receive a primary input. That is, a primary input is connected to the input “i1” of the AND gate 402a and the input “i2” of the AND gate 402b. An output of the AND gate 402a is connected to an input of the NOT gate 404a of the first iteration 502. An output of the NOT gate 404a is connected to a feedback input “i3” of the AND gate 402b of the second iteration 504. An output of the AND gate 402b is connected to an input of the NOT gate 404b of the second iteration 504.

As shown in FIG. 5, the unrolled loop 500 further includes a register 506 connected between the first iteration 502 and the second iteration 504. Specifically, an output of the NOT gate 404b of the second iteration 504 is connected to an input of the register 506, and an output of the register 506 is connected to a feedback input “i4” of the AND gate 402a of the first iteration 502. Thus, the register 501 can break or unroll a feedback loop of the first iteration 502 and the second iteration 504.

The unrolled loop 500 also includes a comparator 508. As shown in FIG. 5, the output of the NOT gate 404a is also connected to a first input of the comparator 508 and the output of the NOT gate 404b is also connected to a second input of the comparator 508. An output of the comparator 508 can output a signal indicating whether the combinational loop 400 corresponding to the unrolled loop 500 would have oscillated should a signal that is input to the unrolled loop 500 be input to the combinational loop 400.

Further, as shown in FIG. 5, the output of the AND gate 402b also serves as an output of the unrolled loop 500, which is also connected to loads 510 for outputting an output signal of the unrolled loop 500 to the loads 510.

Referring again to FIG. 3, at S340, the IC design is verified with the unrolled loop.

In some embodiments, after the combinational loop in the IC design is replaced with the unrolled loop, the IC design with the unrolled loop is verified. The verification of the IC design includes the emulation process and the simulation process. In the emulation process, the IC design is emulated by at least one FPGA. The at least one FPGA is included in a test circuit board and functions of the IC design are verified in the test circuit board. In the simulation process, the IC design is simulated in software running on a computer. The verification of the IC design is performed by placing the simulated IC design in the testbench with stimuli, which is also simulated in software running on the computer.

In the embodiments of the present disclosure, the combinational loop is unrolled into two connected iterations. A register is inserted at the feedback input of the first iteration to suppress oscillation. A comparator is configured to determine whether the oscillation occurs, which can be indicated by the output of the comparator. In other words, the comparator is able to detect the oscillation in the emulation process and the simulation process. Thus, in embodiments of the disclosure, the oscillation can be prevented from occurring in the IC itself and the FPGAs can be prevented from being damaged by the oscillation, while the IC design verification is able to catch potential errors (e.g., providing an oscillation warning) caused by the combinational loop.

FIG. 6 illustrates an example apparatus 600 for verifying an IC design according to some embodiments of the present disclosure. As shown in FIG. 6, the apparatus 600 includes a memory 601 storing program instructions and a processor 602 configured to execute the program instructions to perform the above method 300, including: obtaining a description of the IC design; determining whether the IC design includes a combinational loop based on the description, wherein the combinational loop includes an output and an input connected to the output; and in response to the IC design including the combinational loop, unrolling the combinational loop into an unrolled loop, the unrolled loop including: a first iteration and a second iteration connected to form the unrolled loop, wherein the first iteration includes a first output and a first input, the second iteration includes a second output and a second input, and the second output is connected to the first input; and a register connected between the first input and the second output; and verifying the IC design with the unrolled loop, wherein each of the first iteration and the second iteration includes same components as the combinational loop.

The present disclosure also provides a non-transitory computer-readable storage medium for verifying an IC design. The non-transitory computer-readable storage medium stores a computer program. The computer program is executable by at least one processor of a computing system to cause the computing system to perform the embodiments of the method of verifying the IC design as shown in FIG. 3. The description thereof is omitted.

The non-transitory computer-readable storage medium may be an internal storage unit of the device described in any of the foregoing embodiments. For example, the non-transitory computer-readable storage medium may be a hard disk or an internal memory of the device. The non-transitory computer-readable storage medium may also be an external storage device of the device, such as a plug-in hard disk, a smart media card (SMC), a secure digital (SD) card, a flash card, etc. Further, the non-transitory computer-readable storage medium may also include an internal storage unit and the external storage device. The non-transitory computer-readable storage medium may also store the computer program, and other programs and data required by the device. The non-transitory computer-readable storage medium may also temporarily store already outputted data or to-be-outputted data.

A person of ordinary skill in the art may understand that all or part of the processes in the above-described method embodiments may be implemented by instructing relevant hardware through a computer program. The computer program may be stored in a computer-readable storage medium. When being executed, the computer program may include the processes of the above-described method embodiments. The computer-readable storage medium may be a magnetic disk, an optical disk, a read-only memory (ROM), or a random-access memory (RAM).

Other embodiments of the disclosure will be apparent to those skilled in the art from consideration of the specification and practice of the embodiments disclosed herein. It is intended that the specification and examples be considered as exemplary only and not to limit the scope of the disclosure, with a true scope and spirit of the invention being indicated by the following claims.

What is claimed is:

1. A method of verifying an integrated circuit (IC) design, comprising:
obtaining a description of the IC design;
determining whether the IC design includes a combinational loop based on the description, wherein the combinational loop includes an output and an input connected to the output;
in response to the IC design including the combinational loop, unrolling the combinational loop into an unrolled loop, the unrolled loop including:
a first iteration and a second iteration connected to form the unrolled loop, wherein the first iteration includes a first output and a first input, the second iteration includes a second output and a second input, and the second output is connected to the first input; and
a register connected between the first input and the second output; and
verifying the IC design with the unrolled loop, wherein each of the first iteration and the second iteration includes same components as the combinational loop.

2. The method of claim 1, wherein the unrolled loop further includes a comparator connected to the first iteration and the second iteration and configured to determine whether an oscillation occurs in the combinational loop.

3. The method of claim 2, wherein unrolling the combinational loop further includes:
connecting the first output of the first iteration to a first input of the comparator; and
connecting the second output of the second iteration to a second input of the comparator.

4. The method of claim 3, wherein, in determining whether the oscillation occurs in the combination loop, the comparator is configured to determine whether the first output and the second output are same; and in response to determining the first output and the second output being same, providing a comparison output indicating occurrence of oscillation in the combination loop, and the method further comprises:
generating an oscillation warning in response to receiving from the comparator the comparison output indicating the occurrence of the oscillation.

5. The method of claim 1, further comprising:
connecting a load of the combinational loop to an output of the second iteration.

6. The method of claim 1, wherein the combinational loop further includes a primary input, and the primary input is connected to a third input of the first iteration and a fourth input of the second iteration.

7. The method of claim 1, wherein the description of the IC design includes at least one of a source code in a hardware description language (HDL), a netlist, or a register transfer level (RTL) code.

8. An apparatus for verifying an integrated circuit (IC) design, comprising:
a memory storing program instructions; and
at least one processor configured to execute the program instructions to perform:
obtaining a description of the IC design;
determining whether the IC design includes a combinational loop based on the description, wherein the combinational loop includes an output and an input connected to the output; and
in response to the IC design including the combinational loop, unrolling the combinational loop into an unrolled loop, the unrolled loop including:
a first iteration and a second iteration connected to form the unrolled loop, wherein the first iteration includes a first output and a first input, the second iteration includes a second output and a second input, and the second output is connected to the first input; and
a register connected between the first input and the second output; and
verifying the IC design with the unrolled loop, wherein each of the first iteration and the second iteration includes same components as the combinational loop.

9. The apparatus of claim 8, wherein the unrolled loop further includes a comparator connected to the first iteration and the second iteration and configured to determine whether an oscillation occurs in the combinational loop.

10. The apparatus of claim 9, wherein unrolling the combinational loop further includes:
connecting the first output of the first iteration to a first input of the comparator; and
connecting the second output of the second iteration to a second input of the comparator.

11. The apparatus of claim 10, wherein, in determining whether the oscillation occurs in the combination loop, the comparator is configured to determine whether the first output and the second output are same; and in response to determining the first output and the second output being same, providing a comparison output indicating occurrence of oscillation in the combination loop, and the method further comprises:
generating an oscillation warning in response to receiving from the comparator the comparison output indicating the occurrence of the oscillation.

12. The apparatus of claim 8, further comprising:
connecting a load of the combinational loop to an output of the second iteration.

13. The apparatus of claim 8, wherein the combinational loop further includes a primary input, and the primary input is connected to a third input of the first iteration and a fourth input of the second iteration.

14. The method of claim 8, wherein the description of the IC design includes at least one of a source code in a hardware description language (HDL), a netlist, or a register transfer level (RTL) code.

15. A non-transitory computer-readable storage medium storing a set of instructions, the set of instructions is executable by at least one processor of a computing system to cause the computing system to perform a method for verifying an IC design, the method comprising:
obtaining a description of the IC design;
determining whether the IC design includes a combinational loop based on the description, wherein the combinational loop includes an output and an input connected to the output; and
in response to the IC design including the combinational loop, unrolling the combinational loop into an unrolled loop, the unrolled loop including:
a first iteration and a second iteration connected to form the unrolled loop, wherein the first iteration includes a first output and a first input, the second iteration includes a second output and a second input, and the second output is connected to the first input; and
a register connected between the first input and the second output; and
verifying the IC design with the unrolled loop, wherein each of the first iteration and the second iteration includes same components as the combinational loop.

16. The non-transitory computer-readable storage medium of claim 15, wherein the unrolled loop further includes a comparator connected to the first iteration and the second iteration and configured to determine whether an oscillation occurs in the combinational loop.

17. The non-transitory computer-readable storage medium of claim 16, wherein unrolling the combinational loop further includes:
connecting the first output of the first iteration to a first input of the comparator; and
connecting the second output of the second iteration to a second input of the comparator.

18. The non-transitory computer-readable storage medium of claim 17, wherein, in determining whether the oscillation occurs in the combination loop, the comparator is configured to determine whether the first output and the second output are same; and in response to determining the first output and the second output being same, providing a comparison output indicating occurrence of oscillation in the combination loop, and the method further comprises:
generating an oscillation warning in response to receiving from the comparator the comparison output indicating the occurrence of the oscillation.

19. The non-transitory computer-readable storage medium of claim 15, further comprising:
connecting a load of the combinational loop to an output of the second iteration.

20. The non-transitory computer-readable storage medium of claim 15, wherein the combinational loop further includes a primary input, and the primary input is connected to a third input of the first iteration and a fourth input of the second iteration.
